(19) United States
(12) Patent Application Publication
(10) Pub. No.: US 2025/0239576 A1
(43) Pub. Date: Jul. 24, 2025

(54) OPTICAL CONTROLLER PACKAGE AND OPTOELECTRONIC MEMORY MODULE INCLUDING THE SAME

(71) Applicant: Samsung Electronics Co., Ltd., Suwon-si (KR)

(72) Inventor: Hyunsoo Chung, Suwon-si (KR)

(21) Appl. No.: 18/971,886

(22) Filed: Dec. 6, 2024

(30) Foreign Application Priority Data
Jan. 18, 2024 (KR) 10-2024-0007802

(51) Int. Cl. H01L 25/16; G02B 6/42; H01L 23/00; H01L 23/31; H01L 23/498; H01L 25/18

(52) U.S. Cl. CPC H01L 25/167; G02B 6/4239; H01L 23/3185; H01L 23/49816; H01L 23/49827; H01L 24/24; H01L 25/18; H01L 2224/24226; H01L 2924/1436; H01L 2924/3511

(57) ABSTRACT

An optical controller package includes a first RDL containing a first redistribution wiring structure, a first semiconductor chip on the first RDL and electrically connected to the first redistribution wiring structure and including a logic device, a second RDL on the first semiconductor chip and containing a second redistribution wiring structure electrically connected to the first semiconductor chip, an OE package including a second semiconductor chip on the second RDL and electrically connected to the second redistribution wiring structure and including a PIC, and a third semiconductor chip on and electrically connected to the second semiconductor chip and including an EIC, and a controller adjacent to the OE package on the second RDL and electrically connected to the second redistribution wiring structure.

### CROSS-REFERENCE TO RELATED APPLICATION

This application claims priority under 35 U.S.C. § 119 to Korean Patent Application No. 10-2024-0007802, filed on Jan. 18, 2024, in the Korean Intellectual Property Office (KIPO), the content of which is herein incorporated by reference in its entirety.

### BACKGROUND

### 1. Field

Example embodiments relate to an optical controller package and an optoelectronic memory module including the same.

### 2. Description of the Related Art

A 2.5D package is manufactured by bonding a molded interposer package (MIP) including various types of semiconductor chips and packages mounted on an interposer to an upper surface of a package substrate. The MIP may be bonded onto the package substrate by a thermal compression bonding (TCB) process, however, the MIP and the package substrate may not be well bonded with each other due to the warpage difference between the MIP and the package substrate.

### SUMMARY

Example embodiments provide an optical controller package having enhanced electrical characteristics.

Example embodiments provide an optoelectronic memory module having enhanced electrical characteristics.

According to example embodiments, there is provided an optical controller package. The optical controller package may include a first redistribution layer (RDL) containing a first redistribution wiring structure, a first semiconductor chip on the first RDL and electrically connected to the first redistribution wiring structure and including a logic device, a second RDL on the first semiconductor chip and containing a second redistribution wiring structure electrically connected to the first semiconductor chip, an optical engine (OE) package including a second semiconductor chip on the second RDL and electrically connected to the second redistribution wiring structure and including a photonic integrated circuit (PIC), and a third semiconductor chip on and electrically connected to the second semiconductor chip and including an electronic integrated circuit (EIC), and a controller adjacent to the OE package on the second RDL and electrically connected to the second redistribution wiring structure.

According to example embodiments, there is provided an optoelectronic memory module. The optoelectronic memory module may include a package substrate, an interposer on and electrically connected to the package substrate, an optical controller package including a first redistribution layer (RDL) on the interposer and containing a first redistribution wiring structure electrically connected to the interposer, an optical engine (OE) package on the first RDL and electrically connected to the first redistribution wiring structure and including a photonic integrated circuit (PIC) and an electronic integrated circuit (EIC), a controller adjacent to the OE package on the first RDL and electrically connected to the first redistribution wiring structure, and a first molding member on the first RDL and further being on sidewalls of the OE package and the controller, a memory die stack structure spaced apart from the optical controller package on the interposer and electrically connected to the interposer, and a second molding member on the interposer and further being on sidewalls of the optical controller package and the memory die stack structure.

According to example embodiments, there is provided an optoelectronic memory module. The optoelectronic memory module may include a package substrate, an interposer on and electrically connected to the package substrate, an optical controller package and a core die stack structure. The optical controller package may include a first redistribution layer (RDL) on the interposer and containing a first redistribution wiring structure electrically connected to the interposer, a buffer die on the first RDL and electrically connected to the first redistribution wiring structure, a dummy die spaced apart from the buffer die on the first RDL and electrically connected to the first redistribution wiring structure, a second RDL on and electrically connected to the buffer die and the dummy die and containing a second redistribution wiring structure, an optical engine (OE) package on the first RDL and electrically connected to the first redistribution wiring structure and including a first semiconductor chip including a photonic integrated circuit (PIC) and a second semiconductor chip on and electrically connected to the first semiconductor chip and including an electronic integrated circuit (EIC), a controller adjacent to the OE package on the second RDL and electrically connected to the second redistribution wiring structure, and a core die stack structure spaced apart from the optical controller package in a first direction on the interposer and electrically connected to the interposer and including core dies stacked in a second direction that is perpendicular to the first direction.

The optoelectronic memory module in accordance with example embodiments may include the optical controller package having the controller and the OE package adjacent thereto, and the HBM core stack adjacent to the optical controller package, and the signal transfer distance between the controller and the OE package may decrease so that the low-latency may be acquired even with a low power. The controller may be a compute express link (CXL) controller, and thus the expansion of the HBM core stack connected to a processor may be easy.

### BRIEF DESCRIPTION OF THE DRAWINGS

FIG. 1 is a cross-sectional view illustrating an optoelectronic memory module in accordance with example embodiments, and FIG. 2 is an enlarged cross-sectional view of a high bandwidth memory (HBM) core stack of FIG. 1.

FIGS. 3 to 10 are cross-sectional views illustrating a method of manufacturing a semiconductor package in accordance with example embodiments.

FIG. 11 is a cross-sectional view illustrating an optoelectronic memory module in accordance with example embodiments.

FIG. 12 is a cross-sectional view illustrating an HBM package included in an optoelectronic memory module in accordance with example embodiments.

FIG. 13 is a cross-sectional view illustrating an optoelectronic memory module in accordance with example embodiments.

### DETAILED DESCRIPTION OF EXAMPLE EMBODIMENTS

The above and other aspects and features of the optical controller package and the optoelectronic memory module in accordance with example embodiments will become readily understood from detail descriptions that follow, with reference to the accompanying drawings. The same reference numerals are used for the same components in the drawings, and duplicate descriptions of the same components are omitted. As used herein, the term “and/or” includes any and all combinations of one or more of the associated listed items. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively. It is noted that aspects described with respect to one embodiment may be incorporated in different embodiments although not specifically described relative thereto. That is, all embodiments and/or features of any embodiments can be combined in any way and/or combination.

Hereinafter, a direction substantially perpendicular to an upper surface of each of a wafer, substrate or chip may be referred to as a vertical direction, and a direction substantially parallel to the upper surface of the wafer, substrate or chip may be referred to as a horizontal direction.

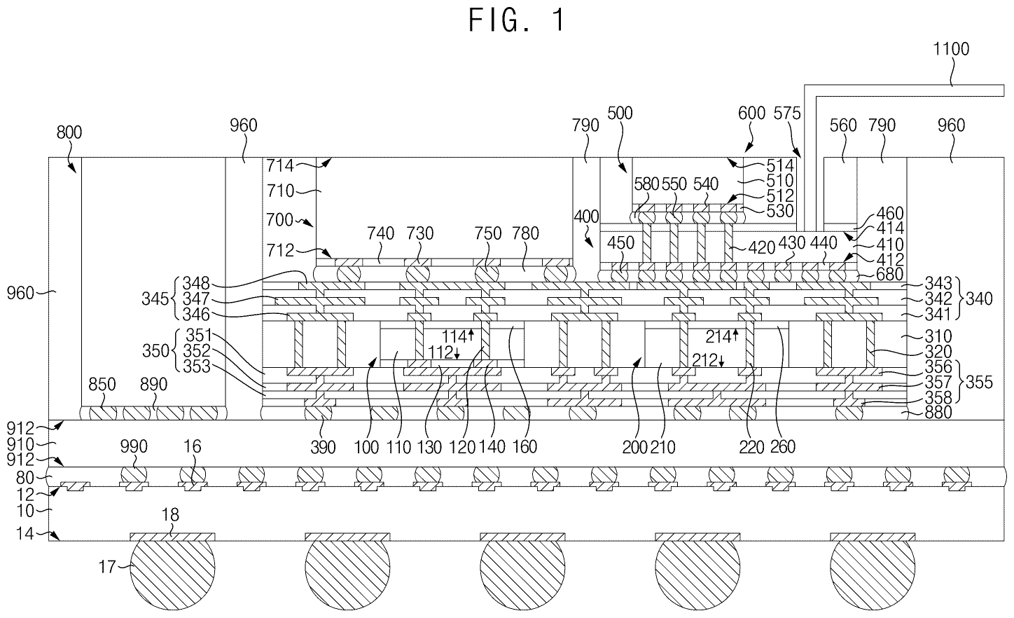

FIG. 1 is a cross-sectional view illustrating an optoelectronic memory module in accordance with example embodiments, and FIG. 2 is an enlarged cross-sectional view of a high bandwidth memory (HBM) core stack of FIG. 1.

Referring to FIGS. 1 and 2, the optoelectronic memory module may include a package substrate 10 and a molded interposer package (MIP) bonded onto the package substrate 10.

The optoelectronic memory module may further include a seventh conductive connection member 30 and a sixth underfill member 80.

The package substrate 10 may include first and second surfaces 12 and 14 opposite to each other in the vertical direction, and may be, e.g., a printed circuit board (PCB). The PCB may be a multi-layered circuit board including various circuit patterns therein, and seventh and eighth conductive pads 16 and 18 of the circuit patterns are shown in FIG. 1. The seventh conductive pad 16 may be disposed on the first surface 12 of the package substrate 10, and the eighth conductive pad 18 may be adjacent to the second surface of the package substrate 10.

In example embodiments, the seventh conductive pad 16 may include a lower portion in a recess on the first surface 12 of the package substrate 10 and an upper portion on and contacting the lower portion, which may protrude upwardly over the first surface 12 of the package substrate 10 in the vertical direction. A width of the upper portion of the seventh conductive pad 16 may be greater than a width of the lower portion of the seventh conductive pad 16. A plurality of seventh conductive pads 16 may be spaced apart from each other in the horizontal direction, and a plurality of eighth conductive pads 18 may be spaced apart from each other in the horizontal direction.

Each of the seventh and eighth conductive pads 16 and 18 may include a metal, e.g., copper, nickel, gold, etc.

The seventh conductive connection member 30 may be disposed beneath (in the vertical direction) the second surface 12 of the package substrate 10, and may contact the eighth conductive pad 18. A plurality of seventh conductive connection members 30 may be spaced apart from each other in the horizontal direction. The seventh conductive connection member 30 may be a bump or a ball including, e.g., solder.

The MIP may include an interposer 910, and an optical controller package and an HBM core stack 800 bonded onto the interposer 910. The MIP may further include fifth and sixth conductive connection members 850 and 990, a fourth molding member 960 and fourth and fifth underfill members 880 and 890.

The interposer 910 may include first and second surfaces 912 and 914 opposite to each other in the vertical direction, and may include a semiconductor material, e.g., silicon or an insulating material, e.g., glass.

A fourth through electrode and fifth and sixth wiring structures electrically connected to the fourth through electrode may be disposed in the interposer 910. Each of the fifth and sixth wiring structures may include wirings, vias, contact plugs, conductive pads, etc., at a plurality of levels, e.g., vertical positions. The fourth through electrode and the fifth and sixth wiring structures may include a conductive material, e.g., a metal, a metal nitride, a metal silicide, etc.

In an example embodiment, the fifth wiring structure may be disposed at a portion of the interposer 910 adjacent to the first surface 912, the sixth wiring structure may be disposed at a portion of the interposer 910 adjacent to the second surface 914, and the fourth through electrode may extend in the vertical direction through a central portion in the vertical direction of the interposer 910, and may contact a portion of each of the fifth and sixth wiring structures to be electrically connected thereto.

The sixth conductive connection member 990 may contact the sixth wiring structure included in the interposer 910 and the seventh conductive pad 16 of the package substrate 10, and may be electrically connected thereto. In example embodiments, a plurality of sixth conductive connection members 990 may be spaced apart from each other in the horizontal direction. The sixth conductive connection member 990 may be a bump or a ball including, e.g., solder.

The sixth underfill member 80 may be disposed between the package substrate 10 and the interposer 910, and may be on and at least partially cover a sidewall of the sixth conductive connection member 990. The sixth underfill member 80 may include an adhesive material containing, e.g., epoxy.

The optical controller package may include first and second redistribution layers (RDLs) 340 and 350, first and second semiconductor chips 100 and 200, an optical engine (OE) package 600 and a controller 700.

The optical controller package may further include a conductive post 310, first, third and fourth conductive connection members 450, 750 and 390, second and third underfill members 680 and 780 and first and third molding members 320 and 790.

The fourth conductive connection member 390 included in the optical controller package may be bonded with the first surface 912 of the interposer 910, and may be electrically connected to the fifth wiring structure. A sidewall of the fourth conductive connection member 390 may be at least partially covered by the fourth underfill member 880. Additionally, the HBM core stack 800 may be bonded to the first surface 912 of the interposer 910 through the fifth conductive connection member 850, and may be electrically connected to the fifth wiring structure. A sidewall of the fifth conductive connection member 850 may be at least partially covered by the fifth underfill member 890.

Each of the fourth and fifth conductive connection members 390 and 850 may be a bump or a ball including, e.g., solder, and each of the fourth and fifth underfill members 880 and 890 may include an adhesive material containing, e.g., epoxy.

The first RDL 340 may include insulation layers stacked in the vertical direction, and a first redistribution wiring structure 345 in the insulation layers. The first redistribution wiring structure 345 may include, e.g., redistribution wirings, vias, contact plugs, conductive pads, etc.

FIG. 1 shows that the first RDL 340 includes first to third insulation layers 341, 342 and 343 sequentially stacked in the vertical direction, and the first redistribution wiring structure 345 includes a first conductive pad 346, a first redistribution wiring 347 and a second redistribution wiring 348 sequentially stacked in the vertical direction upwardly, however, embodiments of the inventive concept may not be limited thereto. Some of the first and second redistribution wirings 347 and 348 may serve as second and third conductive pads, respectively.

The second RDL 350 may include insulation layers stacked in the vertical direction, and a second redistribution wiring structure 355 in the insulation layers. The second redistribution wiring structure 355 may include, e.g., redistribution wirings, vias, contact plugs, conductive pads, etc.

FIG. 1 shows that the second RDL 350 includes fourth to sixth insulation layers 351, 352 and 353 sequentially stacked in the vertical direction, and the second redistribution wiring structure 355 includes a fourth conductive pad 356, a third redistribution wiring 357 and a fourth redistribution wiring 358 sequentially stacked in the vertical direction downwardly, however, embodiments of the inventive concept may not be limited thereto. Some of the third and fourth redistribution wirings 357 and 358 may serve as fifth and sixth conductive pads, respectively.

Each of the first to sixth insulation layers 341, 342, 343, 351, 352 and 353 may include an organic material, e.g., polymer such as polyimide, and each of the first and fourth conductive pads 346 and 356 and each of the first to fourth redistribution wirings 347, 348, 357 and 358 may include a conductive material, e.g., a metal, a metal nitride, a metal silicide, etc.

The first and second RDLs 340 and 350 may be stacked and spaced apart from each other in the vertical direction, and the first and second semiconductor chips 100 and 200 and the conductive post 310 may be disposed between the first and second RDLs 340 and 350. The first and second semiconductor chips 100 and 200 and the conductive post 310 may be covered by the first molding member 320. The first molding member 320 may include, e.g., epoxy molding compound (EMC).

The conductive post 310 may contact some of the first and second redistribution wiring structures 345 and 355 contained in the first and second RDLs 340 and 350, respectively, e.g., the first and second conductive pads 346 and 356 to be electrically connected thereto. In example embodiments, a plurality of conductive posts 310 may be spaced apart from each other in the horizontal direction. The conductive post 310 may include a metal, e.g., copper, aluminum, etc.

The first semiconductor chip 100 may include a first substrate 110 having first and second surfaces 112 and 114 opposite to each other in the vertical direction. A circuit device may be disposed on the first surface 112 of the first substrate 110. The circuit device may include, e.g., a logic device. The circuit device may include circuit patterns, and a first insulating interlayer may be disposed beneath (in the vertical direction) the first surface 112 of the first substrate 110, and may at least partially cover the circuit patterns.

In example embodiments, the first semiconductor chip 100 may be a logic chip for driving the HBM core stack 800. Thus, the first semiconductor chip 100 may also be referred to as a logic die or a buffer die.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

A second insulating interlayer 130 may be disposed beneath the first insulating interlayer, and may contain a first wiring structure 140 therein. The first wiring structure 140 may contact a portion of the second redistribution wiring structure 355 contained in the second RDL 350, e.g., the fourth conductive pad 356, and may be electrically connected thereto. The first insulating interlayer and the second insulating interlayer 130 may include an insulating material, e.g., silicon oxide, silicon nitride, etc.

A first through electrode 120 may extend through the first substrate 110 in the vertical direction, and may include a protrusion portion protruding upwardly (in the vertical direction) over the second surface 114 of the first substrate 110. In example embodiments, a plurality of first through electrodes 120 may be spaced apart from each other in the horizontal direction. The first through electrode 120 may include a conductive material, e.g., a metal, a metal nitride, a metal silicide, etc.

In an example embodiment, the first through electrode 120 may extend through the first substrate 110, and may contact a portion of the circuit patterns in the first insulating interlayer to be electrically connected thereto. In other embodiments, the first through electrode 120 may extend through the first substrate 110 and the first insulating interlayer, and may contact a portion of the first wiring structure 140 in the second insulating interlayer 130, and may be electrically connected thereto.

A first protective pattern structure 160 may be disposed on the second surface 114 of the first substrate 110, and may at least partially surround a sidewall of the protrusion portion of the first through electrode 120 in a plan view of the OE package 600. In example embodiments, the first protective pattern structure 160 may include a first protective pattern and a second protective pattern sequentially stacked in the vertical direction. The first protective pattern may include an oxide, e.g., silicon oxide, and the second protective pattern may include an insulating nitride, e.g., silicon nitride.

The second semiconductor chip 200 may include a second substrate 210 having first and second surfaces 212 and 214 opposite to each other in the vertical direction.

The second substrate 210 may include a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

In example embodiments, the second semiconductor chip 200 may serve as a bridge for electrically connecting the first and second redistribution wiring structures 345 and 355 to each other, which may be disposed in the first and second RDLs 340 and 350, respectively, and thus may be a dummy chip not including an active element. Accordingly, the second semiconductor chip 200 may also be referred to as a dummy die.

A second through electrode 220 may extend through the second substrate 210 in the vertical direction. A protrusion portion of the second through electrode 220 may protrude upwardly over the second surface 214 of the second substrate 210 in the vertical direction. A plurality of second through electrodes 220 may be spaced apart from each other in the horizontal direction. Each of the second through electrodes 220 may contact some of the first and second redistribution wiring structures 345 and 355 contained in the first and second RDLs 340 and 350, respectively, e.g., the first and fourth conductive pads 346 and 356, respectively, and may be electrically connected thereto.

The second through electrode 220 may include a conductive material, e.g., a metal, a metal nitride, a metal silicide, etc.

A second protective pattern structure 260 may be disposed on the second surface 214 of the second substrate 210, and may at least partially surround a sidewall of the protrusion portion of the second through electrode 220 in a plan view of the OE package 600. In example embodiments, the second protective pattern structure 260 may include a third protective pattern and a fourth protective pattern sequentially stacked in the vertical direction. The third protective pattern may include an oxide, e.g., silicon oxide, and the fourth protective pattern may include an insulating nitride, e.g., silicon nitride.

In example embodiments, the first and second semiconductor chips 100 and 200 may be spaced apart from each other in the horizontal direction on the second RDL 350, and may also be spaced apart from the conductive posts 310.

The OE package 600 may include third and fourth semiconductor chips 400 and 500, a second conductive connection member 550, a first underfill member 580, a second molding member 560 and an optical fiber 1100.

The OE package 600 may be bonded to an upper surface of the first RDL 340 through the first conductive connection member 450 and the second underfill 680 at least partially surrounding the first conductive connection member 450 in a plan view of the OE package 600, and may contact a portion of the first redistribution wiring structure 345, e.g., an upper surface of the third conductive pad to be electrically connected thereto. The first conductive connection member 450 may be a bump or a ball including, e.g., solder, and the second underfill member 680 may include an adhesion material containing, e.g., epoxy.

The third semiconductor chip 400 may include a third substrate 410 having first and second surfaces 412 and 414 opposite to each other in the vertical direction. An optical element, e.g., a light waveguide, a photo detector (PD), an optical modulator, etc., may be disposed in the third substrate 410. A third insulating interlayer may be disposed beneath (in the vertical direction) the first surface 412 of the third substrate 410, and may contact a second wiring structure 440.

A third through electrode 420 may extend through the third substrate 410 in the vertical direction, and may be electrically connected to the optical element and the second wiring structure 440. A third protective pattern structure 460 may be disposed on the second surface 414 of the third substrate 410, and may be on and at least partially cover the third through electrode 420. A portion of the second wiring structure 440 may contact the first conductive connection member 450, and may be electrically connected thereto.

The fourth semiconductor chip 500 may include a fourth substrate 510 having first and second surfaces 512 and 514 opposite to each other in the vertical direction. A circuit device, e.g., an amplifier, a current to voltage converter, etc., may be disposed beneath (in the vertical direction) the first surface 512 of the fourth substrate 510. The circuit device may include circuit patterns, which may be at least partially covered by a fourth insulating interlayer beneath (in the vertical direction) the first surface 512 of the fourth substrate 510. A fifth insulating interlayer 530 may be disposed beneath the fourth insulating interlayer, and may contain a third wiring structure 540.

The second conductive connection member 550 may be disposed beneath the fifth insulating interlayer 530, and may contact the third wiring structure 540, and may also contact an upper surface of the third through electrode 420 in the fourth semiconductor chip 500.

The first underfill member 580 may be disposed between the fourth semiconductor chip 500 and the third protective pattern structure 460, and may at least partially surround a sidewall of the second conductive connection member 550 in a plan view of the OE package 600.

The second molding member 560 may be disposed on the third semiconductor chip 400, and may be on and at least partially cover the fourth semiconductor chip 500 and the first underfill member 580.

The optical fiber 1100 may be disposed in a second opening 575, which may be disposed in the second molding member 560 and expose the second surface 414 of the third semiconductor chip 400. The optical fiber 1100 may transfer optical signals from a host to the third semiconductor chip 400.

The fourth substrate 510 may include, e.g., a semiconductor material or a III-V group compound semiconductor. Each of the fourth insulating interlayer and the fifth insulating interlayer 430 may include an insulating material, e.g., silicon oxide, silicon nitride, etc., and the third wiring structure 540 may include a conductive material, e.g., a metal, a metal nitride, a metal silicide, etc. The second conductive connection member 550 may be a bump or a ball including, e.g., solder, and the first underfill member 580 may include an adhesive material containing, e.g., epoxy.

In example embodiments, the third semiconductor chip 400 may include a photonic integrated circuit (PIC), and the fourth semiconductor chip 500 may include an electronic integrated circuit (EIC). Thus, optical signals transferred from the host through the optical fiber 1100 to the third semiconductor chip 400 may be converted into current signals by a PD included in the third semiconductor chip 400, and the current signals may be amplified by an amplifier included in the fourth semiconductor chip 400 and converted into voltage signals by a current to voltage converter.

The controller 700 may be bonded to an upper surface of the first RDL 340 through the third conductive connection member 750 and the third underfill member 780 at least partially surrounding a sidewall of the third conductive connection member 750 in a plan view of the OE package 600, and may contact a portion of the first redistribution wiring structure 345, e.g., an upper surface of the third conductive pad to be electrically connected thereto. The third conductive connection member 750 may be a bump or a ball including, e.g., solder, and the third underfill member 780 may include an adhesive material containing, e.g., epoxy.

In example embodiments, the controller 700 may be disposed adjacent to the OE package 600 on the first RDL 340.

The controller 700 may include a fifth substrate 710 having first and second surfaces 712 and 714 opposite to each other in the vertical direction. A circuit device may be disposed beneath (in the vertical direction) the first surface 712 of the fifth substrate 710. The circuit device may include a logic device. The circuit device may include circuit patterns, which may be at least partially covered by a sixth insulating interlayer beneath the first surface 712 of the fifth substrate 710. A seventh insulating interlayer 730 may be disposed beneath (in the vertical direction) the sixth insulating interlayer, and may contain a fourth wiring structure 740.

In example embodiments, the controller 700 may be a compute express link (CXL) controller.

The fifth substrate 710 may include, e.g., a semiconductor material or a III-V group compound semiconductor. Each of the sixth insulating interlayer and the seventh insulating interlayer 730 may include an insulating material, e.g., silicon oxide, silicon nitride, etc., and the fourth wiring structure 740 may include a conductive material, e.g., a metal, a metal nitride, a metal silicide, etc.

The third molding member 790 may be disposed on the first RDL 350, and may at least partially cover the OE package 600, the controller 700 and the second and third underfill members 680 and 780. The third molding member 790 may include, e.g., EMC.

The HBM core stack 800 may include a plurality of fifth semiconductor chips 1300 and a sixth semiconductor chip 1400 sequentially stacked in the vertical direction.

Each of the fifth and sixth semiconductor chips 1300 and 1400 may be a core die, and may include a memory device. Each of the fifth and sixth semiconductor chips 1300 and 1400 may also be referred to as a memory die or a memory chip. Each of the fifth semiconductor chips 1300 may be a middle core die, and the sixth semiconductor chip 1400 may be a top core die.

FIG. 2 shows that the HBM core stack 800 includes four fifth semiconductor chips 1300 stacked in the vertical direction, however, embodiments of the inventive concept may not be limited thereto, and in some embodiments, may include more than four fifth semiconductor chips 1300.

The MIP may include, for example, a single memory chip or a memory chip stack structure including a plurality of memory chips sequentially stacked, instead of the HBM core stack 800.

The fifth semiconductor chip 1300 may include a sixth substrate 1310 having first and second surfaces 1312 and 1314 opposite to each other in the vertical direction, a fourth through electrode 1320 extending through the sixth substrate 1310, an eighth insulating interlayer and a ninth insulating interlayer 1330 sequentially stacked beneath the first surface 1312 of the sixth substrate 1310, a fourth protective pattern structure 1360 on the second surface 1314 of the sixth substrate 1310, a second bonding layer 1390 on the fourth protective pattern structure 1360 and the fourth through electrode 1320 and containing a second bonding pattern 1395 therein, and a first bonding layer 1380 beneath the ninth insulating interlayer 1330 and containing a first bonding pattern 1385 therein.

The sixth substrate 1310 may include a semiconductor material, e.g., silicon, germanium, silicon-germanium, or a III-V group compound semiconductor, e.g., GaP, GaAs, GaSb, etc. In example embodiments, the sixth substrate 1310 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be disposed beneath the first surface 1312 of the sixth substrate 1310. The circuit device may include circuit patterns, which may be at least partially covered by the eighth insulating interlayer.

The ninth insulating interlayer 1330 may contain a fifth wiring structure 1340 therein. The fifth wiring structure 1340 may include, e.g., wirings, vias, contact plugs, etc., however, is shown as a single structure in FIG. 2 to avoid the complexity of the drawing.

The first bonding pattern 1385 may be disposed beneath (in the vertical direction) the ninth insulating interlayer 1330, and may contact a portion of the fifth wiring structure 1340 to be electrically connected thereto. In example embodiments, a plurality of first bonding patterns 1385 may be spaced apart from each other in the horizontal direction.

The fourth through electrode 1320 may extend through the sixth substrate 1310 in the vertical direction. A protrusion portion of the fourth through electrode 1320 may protrude upwardly over the second surface 1314 of the sixth substrate 1310 in the vertical direction. In example embodiments, a plurality of fourth through electrodes 1320 may be spaced apart from each other in the horizontal direction.

In an example embodiment, the fourth through electrode 1320 may extend through the sixth substrate 1310, and may contact a portion of the circuit patterns in the eighth insulating interlayer to be electrically connected thereto. In other embodiments, the fourth through electrode 1320 may extend through the sixth substrate 1310 and the eighth insulating interlayer, and may contact a portion of the fifth wiring structure 1340 in the ninth insulating interlayer 1330 to be electrically connected thereto.

The fourth protective pattern structure 1360 may be disposed on the second surface 1314 of the sixth substrate 1310, and may at least partially surround a sidewall of the protrusion portion of the sixth through electrode 1320 in a plan view of the HBM core stack 800. In example embodiments, the fourth protective pattern structure 1360 may include a seventh protective pattern and an eighth protective pattern sequentially stacked in the vertical direction on the second surface 1314 of the sixth substrate 1310. The seventh protective pattern may include an oxide, e.g., silicon oxide, and the eighth protective pattern may include an insulating nitride, e.g., silicon nitride.

The second bonding pattern 1395 may contact an upper surface of the fourth through electrode 1320, and a plurality of second bonding patterns 1395 may be spaced apart from each other in the horizontal direction. The second bonding layer 1390 may be disposed on the fourth protective pattern structure 1360, and may at least partially cover a sidewall of the second bonding pattern 1395.

Each of the first and second bonding patterns 1385 and 1395 may include a metal, e.g., copper, and each of the first and second bonding layers 1380 and 1390 may include an insulating nitride, e.g., silicon carbonitride, or an oxide, e.g., silicon oxide.

The eighth insulating interlayer and the ninth insulating interlayer 1330 may include, e.g., silicon oxide or a low-k dielectric material, such as an oxide doped with carbon or fluorine. The fourth through electrode 1320, and the wirings, the vias and the contact plugs included in the fifth wiring structure 1340 may include a conductive material, e.g., a metal, a metal nitride, a metal silicide, etc.

The sixth semiconductor chip 1400 may include a seventh substrate 1410 having first and second surfaces 1412 and 1414 opposite to each other in the vertical direction, a tenth insulating interlayer and an eleventh insulating interlayer 1430 sequentially stacked beneath (in the vertical direction) the first surface 1412 of the seventh substrate 1410, and a third bonding layer 1480 beneath (in the vertical direction) the eleventh insulating interlayer 1430 and containing a third bonding pattern 1485 therein.

The seventh substrate 1410 may include a semiconductor material, e.g., silicon, germanium, silicon-germanium, or a III-V group compound semiconductor, e.g., GaP, GaAs, GaSb, etc. In example embodiments, the seventh substrate 1410 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be disposed beneath (in the vertical direction) the first surface 1412 of the seventh substrate 1410. The circuit device may include circuit patterns, which may be at least partially covered by the tenth insulating interlayer.

The eleventh insulating interlayer 1430 may contain a sixth wiring structure 1440 therein. The sixth wiring structure 1440 may include, e.g., wirings, vias, contact plugs, etc., however, is shown as a single structure in FIG. 2 to avoid the complexity of the drawing.

The third bonding layer 1480 may be disposed beneath (in the vertical direction) the eleventh insulating interlayer 1430, and may at least partially cover a sidewall of the third bonding pattern 1485. The third bonding pattern 1485 may contact a portion of the sixth wiring structure 1440 in the eleventh insulating interlayer 1430 to be electrically connected thereto. The third bonding pattern 1485 may include a metal, e.g., copper, and the third bonding layer 1480 may include an insulating nitride, e.g., silicon carbonitride or an oxide, e.g., silicon oxide.

The tenth insulating interlayer and the eleventh insulating interlayer 1430 may include, e.g., silicon oxide or a low-k dielectric material such as an oxide doped with carbon or fluorine. The vias and the contact plugs included in the sixth wiring structure 1440 may include a conductive material, e.g., a metal, a metal nitride, a metal silicide, etc.

In example embodiments, the fifth semiconductor chips 1300, and the fifth and sixth semiconductor chips 1300 and 1400 included in the HBM core stack 800 may be bonded with each other by a hybrid copper bonding (HCB) process.

Thus, the first bonding layer 1380 of an upper one of the fifth semiconductor chips 1300 and the second bonding layer 1390 of a lower one of the fifth semiconductor chips 1300 may be bonded with each other, and the first bonding pattern 1385 and the second bonding pattern 1395 may contact each other. Additionally, the third bonding layer 1480 of the sixth semiconductor chip 1400 and the second bonding layer 1390 of an uppermost one of the fifth semiconductor chips 1300 may be bonded with each other, and the third bonding pattern 1485 and the second bonding pattern 1395 may contact each other.

However, embodiments of the inventive concept may not be limited thereto, and the fifth semiconductor chips 1300, and the fifth and sixth semiconductor chips 1300 and 1400 included in the HBM core stack 800 may be bonded with each other by a thermal compression bonding (TCB) process.

The fourth molding member 960 may be disposed on the interposer 910, and may be on and at least partially cover the optical controller package, the HBM core stack 800 and the fourth and fifth underfill members 880 and 890. The fourth molding member 960 may include, e.g., EMC.

In the optoelectronic module, the OE package 600 may be disposed adjacent to the controller 700, and the OE package 600 and the controller 700 may collectively form an optical controller package. Optical signals transferred from an outer host through the optical fiber 1100 may be converted into electrical signals and amplified by the third and fourth semiconductor chips 400 and 500 included in the OE package 600, and the electrical signals may be transferred to the controller 700 through the first redistribution wiring structure 345 contained in the first RDL 340.

In the optical controller package, the OE package 600 may be disposed adjacent to the controller 700, and thus a distance of signal transfer between the OE package 600 and the controller 700 may decrease so that the low-latency may be acquired even with a low power.

Additionally, the controller 700 may be electrically connected to the first semiconductor chip 100 serving as a buffer chip through the first redistribution wiring structure 345 contained in the first RDL 340, and the first semiconductor chip 100 may be electrically connected to the HBM core stack 800 through the second redistribution wiring structure 355 contained in the second RDL 350 and the interposer 910.

In example embodiments, the controller 700 may be a CXL controller, and thus the expansion of the HBM core stack 800 connected to an outer processor may be simplified.

The second semiconductor chip 200 may provide an additional electrical connection path between the first and second redistribution wiring structures 345 and 355 contained in the first and second RDLs 340 and 350, respectively, and thus the communication between the OE package 600 and the controller 700 may be faster.

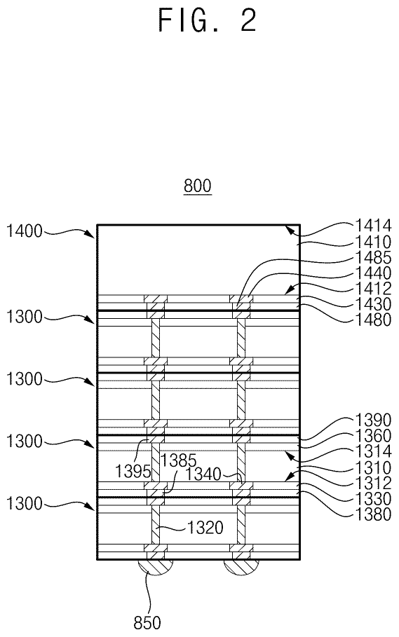

FIGS. 3 to 10 are cross-sectional views illustrating a method of manufacturing a semiconductor package in accordance with example embodiments.

Referring to FIG. 3, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In the die region DA, a circuit device may be formed on the first surface 112 of the first substrate 110. The circuit device may include a logic device. The circuit device may include circuit patterns, and a first insulating interlayer may be formed on the first surface 112 of the first substrate 110 to at least partially cover the circuit patterns.

A second insulating interlayer 130 may be formed on the first insulating interlayer, and may contain a first wiring structure therein.

A first through electrode 120 extending in the vertical direction through an upper portion of the first substrate 110, that is, a portion of the first substrate 110 adjacent to the first surface 112 thereof, may be formed. The first through electrode 120 may contact a portion of the circuit patterns, and may be electrically connected thereto.

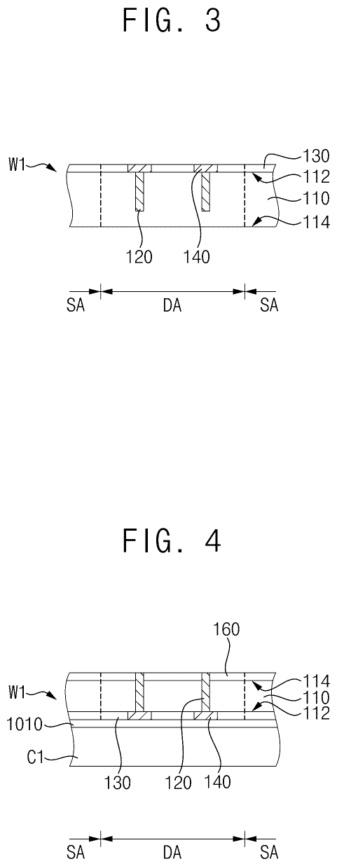

Referring to FIG. 4, a first temporary adhesion layer 1010 may be attached to a first carrier substrate C1, the first temporary adhesion layer 1010 may be bonded with an upper surface of the second insulating interlayer 130, and the first carrier substrate C1 may be flipped.

The first carrier substrate C1 may include, e.g., a non-metal or metal plate, a silicon substrate, a glass substrate, etc. The first temporary adhesion layer 1010 may include a material that loses adhesion in response to irradiation of light, e.g., UV light or heat. In an example embodiment, the first temporary adhesion layer 1010 may include release tape or glue.

A portion of the first substrate 110 adjacent to the second surface 114 of the first substrate 110 may be removed by, e.g., a grinding process to at least partially expose an upper portion of the first through electrode 120, a first protective layer structure may be formed on the second surface 114 of the first substrate 110 to at least partially cover the first through electrode 120, and a planarization process may be performed on the first protective layer structure until an upper surface of the first through electrode 120 is exposed to form a first protective pattern structure 160.

In example embodiments, the planarization process may include a chemical mechanical polishing (CMP) process and/or an etch back process.

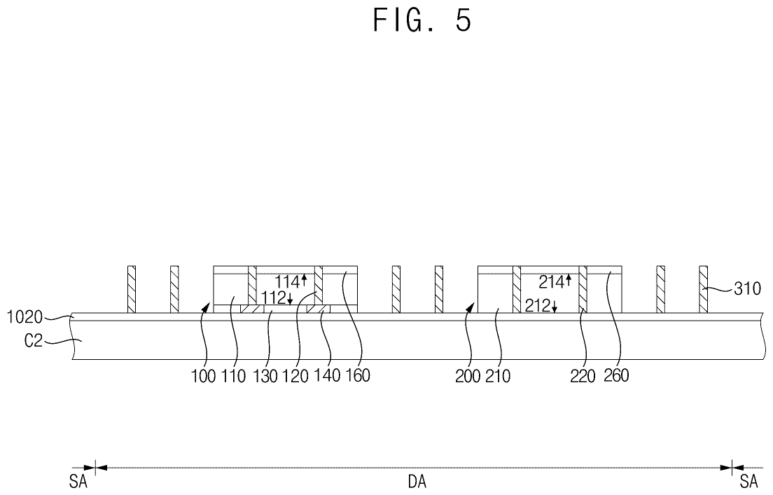

Referring to FIG. 5, a second temporary adhesion layer 1020 may be attached to a second carrier substrate C2, and a conductive post 310 may be formed on the second temporary adhesion layer 1020.

In example embodiments, the second carrier substrate C2 may include a plurality of die regions DA and a scribe lane region SA at least partially surrounding each of the die regions DA in a plan view.

The conductive post 310 may be formed by forming a first photoresist layer on the second temporary adhesion layer 1020, performing an exposure process and a developing process on the first photoresist layer to form a first photoresist pattern including a first opening, and performing, e.g., an electroplating process. The first photoresist pattern may be removed by, e.g., an ashing process and/or a stripping process. In example embodiments, a plurality of conductive posts 310 may be formed to be spaced apart from each other in the horizontal direction on the second temporary adhesion layer 1020.

The first wafer W1 may be cut along the scribe lane region SA by a sawing process into first semiconductor chips 100, and the first temporary adhesion layer 1010 attached to the first carrier substrate C1 may be separated from the second insulating interlayer 130 so that the first carrier substrate C1 may be separated from each of the first semiconductor chips 100. Each of the first semiconductor chips 100 may be bonded onto the second temporary adhesion layer 1020. Particularly, the second insulating interlayer 130 containing the first wiring structure 140 may contact an upper surface of the second temporary adhesion layer 1020 so that the first semiconductor chip 100 may be bonded with the second temporary adhesion layer 1020.

Additionally, the second semiconductor chip 200 may be bonded onto the second temporary adhesion layer 1020.

The second semiconductor chip 200 may include a second substrate 210 having first and second surfaces 212 and 214 opposite to each other in the vertical direction. A second through electrode 220 may extend through the second substrate 210 in the vertical direction, and a second protective pattern structure 260 may be formed on the second surface 214 of the second substrate 210 to at least partially cover the second through electrode 220.

In example embodiments, the first and second semiconductor chips 100 and 200 may be spaced apart from each other in the horizontal direction on the second temporary adhesion layer 1020, and may also be spaced apart from the conductive posts 310. The first and second semiconductor chips 100 and 200 and the conductive posts 310 may be disposed on each of the die regions DA of the first carrier substrate C1.

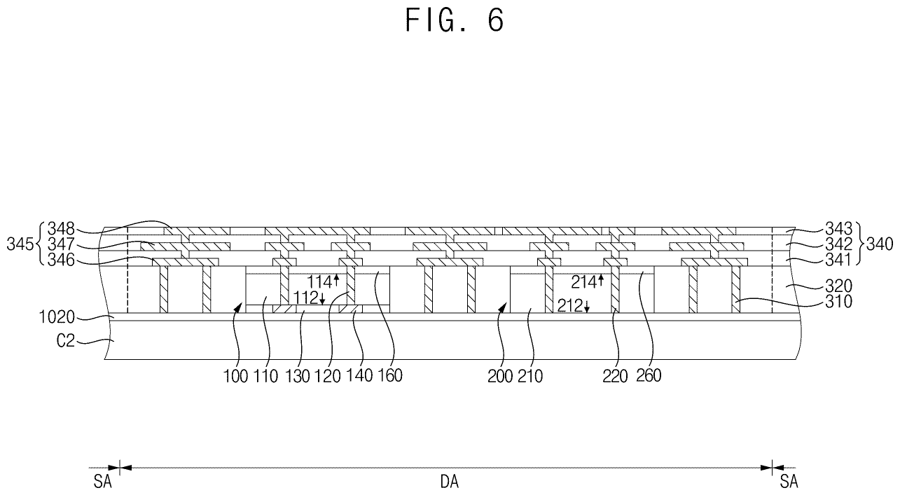

Referring to FIG. 6, a first molding member 320 may be formed on the second temporary adhesion layer 1020 to at least partially cover the first and second semiconductor chips 100 and 200 and the conductive posts 310, and a planarization process may be performed on the first molding member 320 to remove an upper portion of the first molding member 320.

A first RDL 340 may be formed on the first molding member 320, the first and second semiconductor chips 100 and 200 and the conductive posts 310. In example embodiments, the first RDL 340 may include insulation layers stacked in the vertical direction and a first redistribution wiring structure 345 in the insulation layers. The first redistribution wiring structure 345 may include, e.g., redistribution wirings, vias, contact plugs, conductive pads, etc.

FIG. 6 shows that the first RDL 340 includes first to third insulation layers 341, 342 and 343 sequentially stacked in the vertical direction, and the first redistribution wiring structure 345 includes a first conductive pad 346, a first redistribution wiring 347 and a second redistribution wiring 348 sequentially stacked in the vertical direction, however, embodiments of the inventive concept may not be limited thereto.

For example, the first RDL 340 may be formed by the following processes.

The first conductive pad 346 may be formed on the first molding member 320, the first and second semiconductor chips 100 and 200 and the conductive posts 310, the first insulation layer 341 may be formed on the first molding member 320, the first and second semiconductor chips 100 and 200 and the conductive posts 310 to cover the first conductive pad 346, and the first insulation layer 341 may be partially removed to form a first hole at least partially exposing an upper surface of the first conductive pad 346.

A first seed layer may be formed on an upper surface of the first insulation layer 341, a sidewall of the first hole and the upper surface of the of the first conductive pad 346 at least partially exposed by the first hole, an electroplating process or an electroless plating process may be performed to form a first redistribution wiring layer at least partially filling the first hole, the first redistribution wiring layer may be patterned to form the first redistribution wiring 347, and a portion of the first seed layer not covered by the first redistribution wiring 347 may be removed. The first redistribution wiring 347 may contact the upper surface of the first conductive pad 346 through the first hole, and a portion of the first redistribution wiring 347 may serve as a second conductive pad.

The second insulation layer 342 may be formed on the first insulation layer 341 to at least partially cover the first redistribution wiring 347, the second insulation layer 342 may be partially removed to form a second hole at least partially exposing an upper surface of the second conductive pad of the first redistribution wiring 347, a second seed layer may be formed on an upper surface of the second insulation layer 342, a sidewall of the second hole and the upper surface of the of the second conductive pad may be at least partially exposed by the second hole, an electroplating process or an electroless plating process may be performed to form a second redistribution wiring layer at least partially filling the second hole, the second redistribution wiring layer may be patterned to form the second redistribution wiring 348, and a portion of the second seed layer not covered by the second redistribution wiring 348 may be removed. The second redistribution wiring 348 may contact the upper surface of the second conductive pad of the first redistribution wiring 347 through the second hole.

The third insulation layer 343 may be formed on the second insulation layer 342 to at least partially cover the second redistribution wiring 348, and a planarization process may be performed on the third insulation layer 343 until an upper surface of the second redistribution wiring 348 is exposed so that the third insulation layer 343 may at least partially cover a sidewall of the second redistribution wiring 348. A portion of the second redistribution wiring 348 may serve as a third conductive pad.

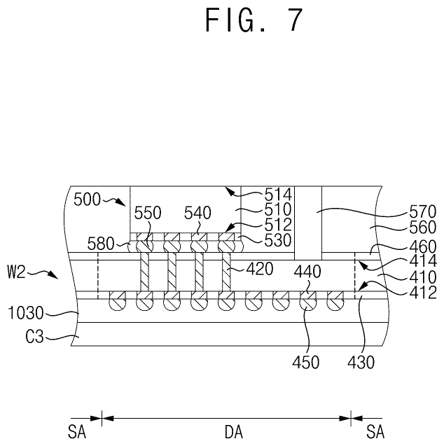

Referring to FIG. 7, a fourth semiconductor chip 500 including an electronic integrated circuit (EIC) may be bonded to an upper surface of the second wafer W2 including a plurality of a photonic integrated circuits (PIC).

In example embodiments, the second wafer W2 may include a third substrate 410 having first and second surfaces 412 and 414 opposite to each other in the vertical direction. Additionally, the second wafer W2 may include a plurality of die regions DA and a scribe lane region SA at least partially surrounding each of the die regions DA in a plan view. The first wafer W1 may be cut along the scribe lane region SA by a sawing process to be singulated into a plurality of third semiconductor chips.

In the die region DA, an optical device, e.g., a light waveguide, a laser diode, an optical modulator, etc., may be formed. Additionally, a third insulating interlayer 430 may be formed beneath (in the vertical direction) the first surface 412 of the third substrate 410, and may contact a second wiring structure 440 therein.

A third through electrode 420 may extend through the third substrate 410 in the vertical direction, and may be electrically connected to the optical device and the second wiring structure 440. A third protective pattern structure 460 may be formed on the second surface 414 of the third substrate 410 to at least partially cover the third through electrode 420. A first conductive connection member 450 may be formed beneath (in the vertical direction) the third insulating interlayer 430, and may be electrically connected to the second wiring structure 440.

The second wafer W2 may be formed on the third carrier substrate C3 through a third temporary adhesion layer 1030 beneath the third insulating interlayer 430. The third temporary adhesion layer 1030 may at least partially cover the first conductive connection member 450.

The fourth semiconductor chip 500 may include a fourth substrate 510 having first and second surfaces 512 and 514 opposite to each other in the vertical direction. A circuit device may be disposed beneath (in the vertical direction) the first surface 512 of the fourth substrate 510. The circuit device may include circuit patterns, and a fourth insulating interlayer may be formed beneath the first surface 512 of the fourth substrate 510 to at least partially cover the circuit patterns. A fifth insulating interlayer 530 may be formed beneath the fourth insulating interlayer, and may contact a third wiring structure 540 therein.

In example embodiments, the fourth semiconductor chip 500 may be bonded onto the second wafer W2 by a TCB process. Thus, a second conductive connection member 550 may be formed beneath the fifth insulating interlayer 530, and may be electrically connected to the third wiring structure 540. The second conductive connection member 550 may contact an upper surface of the third through electrode 420 of the second wafer W2. A first underfill member 580 may be formed between the fourth semiconductor chip 500 and the third protective pattern structure 460, and may at least partially cover the second conductive connection member 550.

A second molding member 560 may be formed on the second wafer W2 to at least partially cover the fourth semiconductor chip 500 and the first underfill member 580, and a planarization process may be performed on the second molding member 560 until an upper surface of the fourth semiconductor chip 500 is exposed so that an upper portion of the second molding member 560 may be removed.

A portion of the second molding member 560 and a portion of the third protective pattern structure 460 thereunder may be removed to form a second opening exposing the second surface 414 of the third substrate 410 of the second wafer W2, and a sacrificial layer 570 may be formed in the second opening. In an example embodiment, the sacrificial layer 570 may include a photoresist layer.

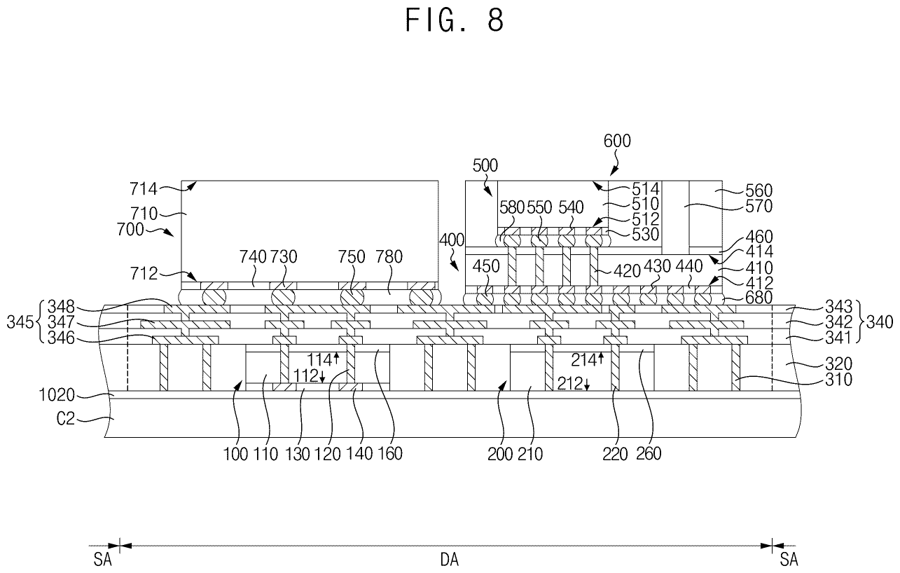

Referring to FIG. 8, the second wafer W2 may be cut along the scribe lane region SA by a sawing process into third semiconductor chips 400, and the third temporary adhesion layer 1030 attached to the third carrier substrate C3 may be separated from the third insulating interlayer 430 so that the third carrier substrate C3 may be separated from each of the third semiconductor chips 400.

Thus, an optical engine (OE) package 600 include the fourth semiconductor chip 500 and the second molding member 560 may be formed on each of the third semiconductor chips 400.

The OE package 600 and a controller 700 may be stacked on an upper surface of the first RDL 340 on the second carrier substrate C2 to be spaced apart from each other in the horizontal direction.

The controller 700 may include a fifth substrate 710 having first and second surfaces 712 and 714 opposite to each other in the vertical direction. A circuit device may be formed beneath (in the vertical direction) the first surface 712 of the fifth substrate 710. The circuit device may include circuit patterns, which may be at least partially covered by a sixth insulating interlayer. A seventh insulating interlayer 730 may be formed beneath (in the vertical direction) the sixth insulating interlayer, and may contain a fourth wiring structure 740 therein.

In example embodiments, each of the OE package 600 and the controller 700 may be bonded to the upper surface of the first RDL 340 by a TCB process. Thus, the OE package 600 may be bonded to the upper surface of the first RDL 340 through the first conductive connection member 450 and a second underfill member 680 at least partially surrounding the first conductive connection member 450 in a plan view of the OE package 600, and the controller 700 may be bonded to the upper surface of the first RDL 340 through a third conductive connection member 750 and a third underfill member 780.

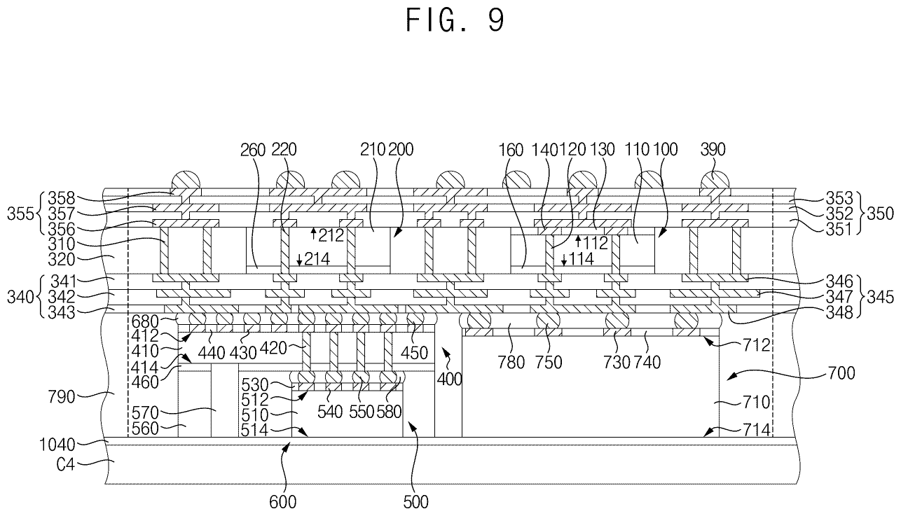

Referring to FIG. 9, a third molding member 790 may be formed on the first RDL 340 to cover the OE package 600, the controller 700 and the second and third underfill members 680 and 780, and a planarization process may be performed on the third molding member 790 until an upper surface of the OE package 600 is at least partially exposed to remove an upper portion of the third molding member 790.

A fourth temporary adhesion layer 1040 and a fourth carrier substrate C4 may be attached onto the third molding member 790, the OE package 600 and the controller 700, and may be flipped. The second temporary adhesion layer 1020 attached to the second carrier substrate C2 may be separated from the first and second semiconductor chips 100 and 200, the conductive posts 310 and the first molding member 320 so that the second carrier substrate C2 may be separated therefrom.

The fourth carrier substrate C4 may include a plurality of die regions DA and a scribe lane region SA at least partially surrounding each of the die regions DA in a plan view of the OE package 600, and a structure on the fourth carrier substrate C4 may be cut along the scribe lane region SA by a sawing process to be singulated into a plurality of optical controller packages on the die regions DA, respectively.

A second RDL 350 containing a second redistribution wiring structure 355 may be formed on the first and second semiconductor chips 100 and 200, the conductive posts 310 and the first molding member 320, and a fourth conductive connection member 390 may be formed on the second RDL 350.

The second RDL 350 may include fourth to sixth insulation layers 351, 352 and 353 sequentially stacked, and the second redistribution wiring structure 355 may include a fourth conductive pad 356 and third and fourth redistribution wirings 357 and 358. Portions of the third and fourth redistribution wirings 357 and 358 may serve as fifth and sixth conductive pads, respectively.

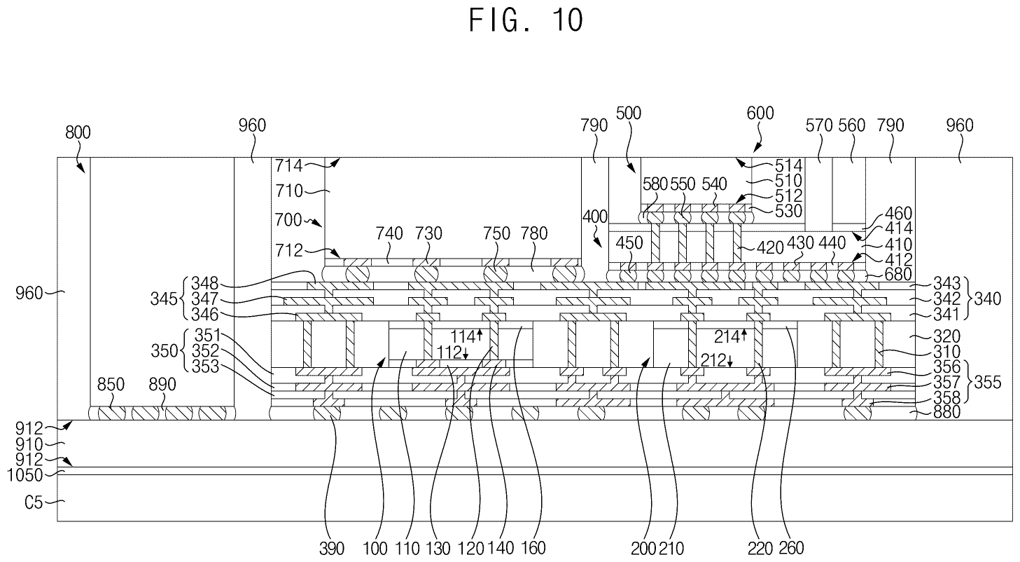

Referring to FIG. 10, the fourth carrier substrate C4 and the structure on the fourth carrier substrate C4 may be cut along the scribe lane region SA by a sawing process to be singulated into a plurality of optical controller packages, and the fourth temporary adhesion layer 1040 attached to the fourth carrier substrate C4 may be separated from the OE package 600, the controller 700 and the third molding member 790 so that the fourth carrier substrate C4 may be separated from each of the optical controller packages.

The optical controller package and the HBM core stack 800 may be bonded onto an interposer 910.

The interposer 910 may include first and second surfaces 912 and 914 opposite to each other in the vertical direction, and may be stacked on a fifth carrier substrate C5 through a fifth temporary adhesion layer 1050 beneath (in the vertical direction) the second surface 914.

In example embodiments, each of the optical controller package and the HBM core stack 800 may be bonded to the first surface 912 of the interposer 910 by a TCB process. Thus, the optical controller package may be bonded to the upper surface of the interposer 910 through the fourth conductive connection member 390 and a fourth underfill member 880 at least partially surrounding the fourth conductive connection member 390 in a plan view of the OE package 600, and the HBM core stack 800 may be bonded to the upper surface of the interposer 910 through a fifth conductive connection member 850 and a fifth underfill member 890 at least partially surrounding the fifth conductive connection member 850 in a plan view of the OE package 600.

A fourth molding member 960 may be formed on the interposer 910 to at least partially cover the optical controller package, the HBM core stack 800 and the fourth and fifth underfill members 880 and 890, and a planarization process may be performed on the fourth molding member 960 until upper surfaces of the optical controller package and the HBM core stack 800 are at least partially exposed to remove an upper portion of the fourth molding member 960.

Referring to FIG. 1 again, the fifth temporary adhesion layer 1050 and the fifth carrier substrate C5 may be separated from the interposer 910, and a sixth conductive connection member 990 may be formed beneath (in the vertical direction) the second surface 914 of the interposer 910 to form a molded interposer package (MIP), and the MIP may be bonded onto a package substrate 10.

The package substrate 10 may include first and second surfaces 12 and 14 opposite to each other in the vertical direction, and may be, e.g., a printed circuit board (PCB). The PCB may be a multi-layered circuit board including various circuit patterns therein, and seventh and eighth conductive pads 16 and 18 of the circuit patterns are shown in FIG. 1. The seventh conductive pad 16 may be disposed on the first surface 12 of the package substrate 10, and the eighth conductive pad 18 may be adjacent to the second surface of the package substrate 10.

A seventh conductive connection member 30 may be disposed beneath (in the vertical direction) the second surface 12 of the package substrate 10, and may contact the eighth conductive pad 18.

In example embodiments, the MIP may be bonded onto the package substrate 10 through the sixth conductive connection member 990 and a sixth underfill member 80 by a TCB process.

The sacrificial layer 570 may be removed to form the second opening 575 again that may at least partially expose the second surface 414 of the third substrate 410, and an optical fiber 1100 may be formed in the second opening 575 to complete the manufacturing the optoelectronic memory module.

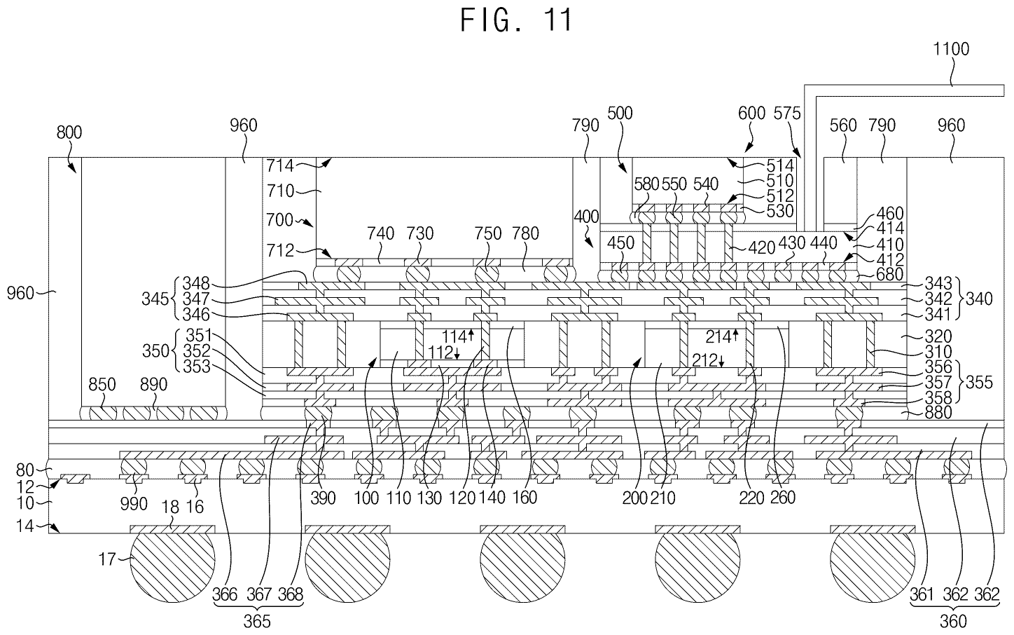

FIG. 11 is a cross-sectional view illustrating an optoelectronic memory module in accordance with example embodiments. This optoelectronic memory module may be substantially the same as or similar to that of FIGS. 1 and 2, except for including a third RDL instead of the interposer, and thus repeated explanations are omitted herein.

Referring to FIG. 11, a third RDL 360 containing a third redistribution wiring structure 365 may be formed between the package substrate 10 and the optical controller package and the HBM core stack 800 instead of the interposer 910.

Thus, the optical controller package and the HBM core stack 800 may be electrically connected to each other through the third redistribution wiring structure 365.

In an example embodiment, the third RDL 350 may include seventh to ninth insulation layers 361, 362 and 363 sequentially stacked in the vertical direction, and the third redistribution wiring structure 365 may include a seventh conductive pad 366 and fifth and sixth redistribution wirings 367 and 368. Portions of the fifth and sixth wirings 367 and 368 may serve as eighth and ninth conductive pads, respectively.

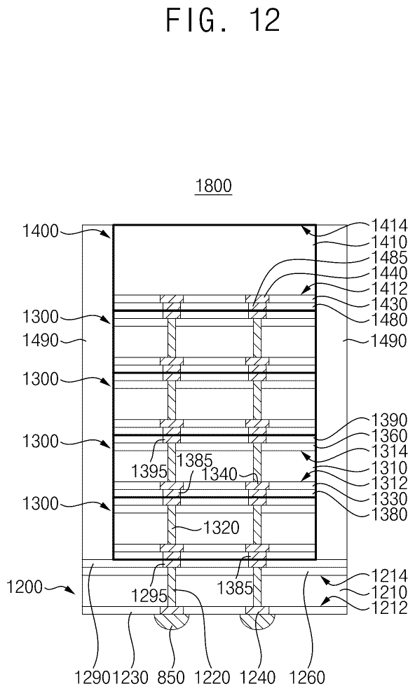

FIG. 12 is a cross-sectional view illustrating an HBM package included in an optoelectronic memory module in accordance with example embodiments. This optoelectronic memory module may be substantially the same as or similar to that of FIGS. 1 and 2, except for including the HBM package instead of the HBM core stack 800, and thus repeated explanations are omitted herein.

Referring to FIG. 12, an HBM package 1800 may include a seventh semiconductor chip 1200 in addition to the HBM core stack 800 of FIGS. 1 and 2.

That is, the HBM package 1800 may include the seventh semiconductor chip 1200, and the fifth semiconductor chips 1300 and the sixth semiconductor chip 1400 sequentially stacked on the seventh semiconductor chip 1200. Additionally, the HBM package 1800 may further include a fifth molding member 1490.

In example embodiments, the seventh semiconductor chip 1200 may be a buffer die, and may include a logic device. Thus, the seventh semiconductor chip 1200 may also be referred to as a logic die or a logic chip.

The seventh semiconductor chip 1200 may include an eighth substrate 1210 having first and second surfaces 1212 and 1214 opposite to each other in the vertical direction, a fifth through electrode 1220 extending through the eighth substrate 1210, a twelfth insulating interlayer and a thirteenth insulating interlayer 1230 sequentially stacked beneath the first surface 1212 of the eighth substrate 1210 in the vertical direction, a fifth protective pattern structure 1260 on the second surface 1214 of the eighth substrate 1210, and a fourth bonding layer 1290 containing a fourth bonding pattern 1295 on the fifth protective pattern structure 1260 and the fifth through electrode 1220.

In example embodiments, the seventh semiconductor chip 1200 may have a planar area greater than that of each of the fifth and sixth semiconductor chips 1300 and 1400, and the fifth molding member 1490 may be disposed on the seventh semiconductor chip 1200 and at least partially cover sidewalls of the fifth and sixth semiconductor chips 1300 and 1400.

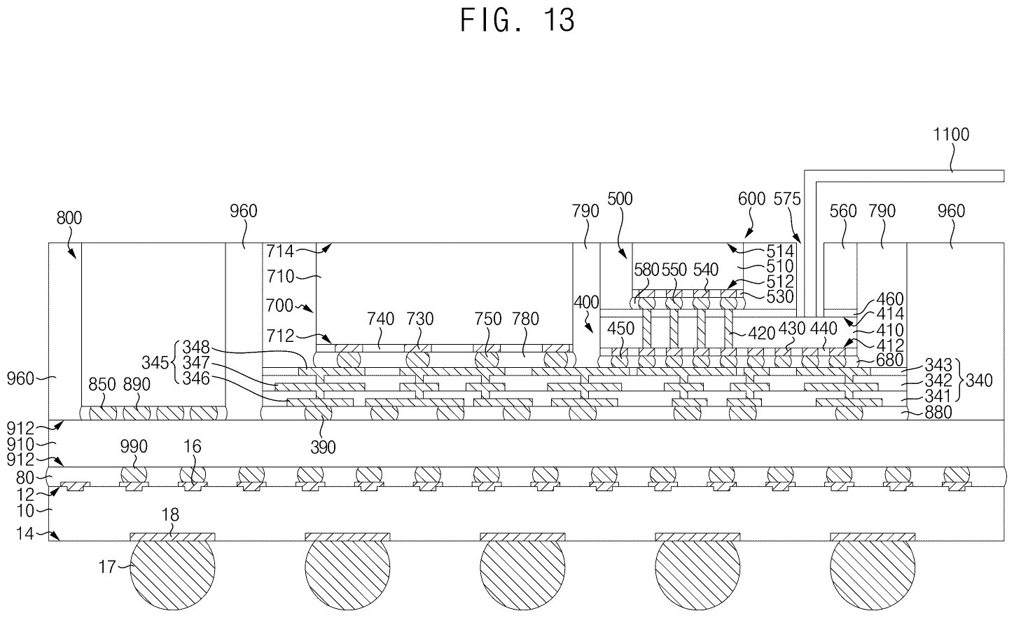

FIG. 13 is a cross-sectional view illustrating an optoelectronic memory module in accordance with example embodiments. This optoelectronic memory module may be substantially the same as or similar to that of FIGS. 1 and 2, except for some elements, and thus repeated explanations are omitted herein.

Referring to FIG. 13, the optoelectronic memory module may include the HBM package 1800 instead of the HBM core stack 800, and thus a buffer die may be included in the HBM package 1800 so that the optoelectronic memory module may not include the first semiconductor chip 100 serving as a buffer die.

Additionally, the optoelectronic memory module may not include the second semiconductor chip 200 and the conductive posts 310 spaced apart from the first semiconductor chip 100 in the horizontal direction, and may include only one of the first and second RDLs 340 and 350, e.g., only the first RDL 340.

Thus, the optical controller package may include the first RDL 340, the OE package 600 and the controller 700, and may communicate with the HBM package 1800 through the first redistribution wiring structure 345 contained in the first RDL 340 and the interposer 910.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of example embodiments as defined in the claims.

What is claimed is:

1. An optical controller package comprising:
a first redistribution layer (RDL) containing a first redistribution wiring structure;
a first semiconductor chip on the first RDL, the first semiconductor chip being electrically connected to the first redistribution wiring structure and including a logic device;
a second RDL on the first semiconductor chip, the second RDL containing a second redistribution wiring structure electrically connected to the first semiconductor chip;
an optical engine (OE) package including:
a second semiconductor chip on the second RDL, the second semiconductor chip being electrically connected to the second redistribution wiring structure and including a photonic integrated circuit (PIC); and
a third semiconductor chip on and electrically connected to the second semiconductor chip, the third semiconductor chip including an electronic integrated circuit (EIC); and
a controller adjacent to the OE package on the second RDL, the controller being electrically connected to the second redistribution wiring structure.

2. The optical controller package according to claim 1, further comprising a fourth semiconductor chip between the first and second RDLs, the fourth semiconductor chip being electrically connected to the first and second redistribution wiring structures, respectively.

3. The optical controller package according to claim 2, wherein the fourth semiconductor chip includes:
a substrate including a semiconductor material; and
a through electrode extending through the substrate, the through electrode contacting the first and second redistribution wiring structures.

4. The optical controller package according to claim 1, further comprising a conductive post between the first and second RDLs, the conductive post being electrically connected to the first and second redistribution wiring structures.

5. The optical controller package according to claim 1, further comprising a molding member on the second RDL, the molding member further being on sidewalls of the OE package and the controller.

6. The optical controller package according to claim 5, further comprising an optical fiber in an opening extending through the molding member, the optical fiber being communicatively connected to the second semiconductor chip.

7. An optoelectronic memory module comprising:
a package substrate;
an interposer on and electrically connected to the package substrate;
an optical controller package including:
a first redistribution layer (RDL) on the interposer, the first RDL containing a first redistribution wiring structure electrically connected to the interposer;
an optical engine (OE) package on the first RDL, the OE package being electrically connected to the first redistribution wiring structure and including a photonic integrated circuit (PIC) and an electronic integrated circuit (EIC);
a controller adjacent to the OE package on the first RDL, the controller being electrically connected to the first redistribution wiring structure; and
a first molding member on the first RDL, the first molding member further being on sidewalls of the OE package and the controller;
a memory die stack structure spaced apart from the optical controller package on the interposer, the memory die stack structure being electrically connected to the interposer; and
a second molding member on the interposer, the second molding member further being on sidewalls of the optical controller package and the memory die stack structure.

8. The optoelectronic memory module according to claim 7, further comprising a second RDL and a first semiconductor chip sequentially stacked between the interposer and the first RDL,
wherein the second RDL includes a second redistribution wiring structure electrically connected to the interposer and the first redistribution wiring structure, and
wherein the first semiconductor chip is electrically connected to the first and second redistribution wiring structures.

9. The optoelectronic memory module according to claim 8, wherein the first semiconductor chip is a buffer die including a logic device.

10. The optoelectronic memory module according to claim 8, further comprising a second semiconductor chip spaced apart from the first semiconductor chip on the second RDL, the second semiconductor chip being electrically connected to the first and second redistribution wiring structures.

11. The optoelectronic memory module according to claim 10, further comprising a third molding member between the first and second RDLs, the third molding member further being on sidewalls of the first and second semiconductor chips.

12. The optoelectronic memory module according to claim 8, further comprising a conductive post spaced apart from the first semiconductor chip on the second RDL, the conductive post being electrically connected to the first and second redistribution wiring structures.

13. The optoelectronic memory module according to claim 7, wherein the OE package includes:
a first semiconductor chip on the first RDL, the first semiconductor chip being electrically connected to the first redistribution wiring structure and including a photonic integrated circuit (PIC); and
a second semiconductor chip on and electrically connected to the first semiconductor chip, the second semiconductor chip including an electronic integrated circuit (EIC).

14. The optoelectronic memory module according to claim 13, wherein the OE package further includes an optical fiber in an opening extending through the third molding member, the optical fiber being communicatively connected to the first semiconductor chip.

15. The optoelectronic memory module according to claim 7, wherein the memory die stack structure includes a high bandwidth memory (HBM) core stack.

16. The optoelectronic memory module according to claim 7, further comprising a buffer die between and electrically connected to the interposer and the memory die stack structure.

17. An optoelectronic memory module comprising:
a package substrate;
an interposer on and electrically connected to the package substrate;
an optical controller package including:
a first redistribution layer (RDL) on the interposer, the first RDL containing a first redistribution wiring structure electrically connected to the interposer;
a buffer die on the first RDL, the buffer die being electrically connected to the first redistribution wiring structure;
a dummy die spaced apart from the buffer die on the first RDL, the dummy die being electrically connected to the first redistribution wiring structure;
a second RDL on and electrically connected to the buffer die and the dummy die, the second RDL containing a second redistribution wiring structure;
an optical engine (OE) package on the first RDL, the OE package being electrically connected to the first redistribution wiring structure and including:
a first semiconductor chip including a photonic integrated circuit (PIC); and
a second semiconductor chip on and electrically connected to the first semiconductor chip, the second semiconductor chip including an electronic integrated circuit (EIC);
a controller adjacent to the OE package on the second RDL, the controller being electrically connected to the second redistribution wiring structure; and
a core die stack structure spaced apart from the optical controller package in a first direction on the interposer, the core die stack being electrically connected to the interposer and including core dies stacked in a second direction that is perpendicular to the first direction.

18. The optoelectronic memory module according to claim 17, further comprising a conductive post between the first and second RDLs, the conductive post being spaced apart from the buffer die and the dummy die in the first direction and electrically connected to the first and second redistribution wiring structures.

19. The optoelectronic memory module according to claim 17, further comprising:
a first molding member between the first and second RDLs, the first molding member being on sidewalls of the buffer die and the dummy die;
a second molding member on the second RDL, the second molding member being on sidewalls of OE package and the controller; and
a third molding member on the interposer, the third molding member being on sidewalls of the optical controller package and the core die stack.
